(19) United States
(12) Patent Application Publication
(10) Pub. No.: US 2013/0069650 A1
(43) Pub. Date: Mar. 21, 2013

(54) MAGNETIC RESONANCE IMAGING APPARATUS AND HIGH-FREQUENCY MAGNETIC FIELD PULSE MODULATION METHOD

(71) Applicant: Takayuki Abe, Tokyo (JP)

(72) Inventor: Takayuki Abe, Tokyo (JP)

(73) Assignee: HITACHI MEDICAL CORPORATION, Tokyo (JP)

(21) Appl. No.: 13/699,062

(22) PCT Filed: May 11, 2011
(86) PCT No.: PCT/JP2011/060820

§ 371 Date: Nov. 20, 2012

(30) Foreign Application Priority Data
May 28, 2010 (JP) 2010-123096

(51) Int. Cl. G01R 33/565; G01R 33/34

(52) U.S. Cl. CPC G01R 33/565; G01R 33/34
USPC 324/309; 324/322

(57) ABSTRACT

Degradation of the slice excitation characteristics is prevented by making it possible to modulate a high frequency magnetic field pulse on the basis of a gradient magnetic field response that is actually used. In order to do so, an imaging pulse sequence including first and second measurement sequences is executed. In the first measurement sequence, the same slice selection gradient magnetic field pulse as a slice selection gradient magnetic field pulse used in the second measurement sequence is used. The phase of a magnetic resonance signal measured by the first measurement sequence is differentiated, and the waveform of the high frequency magnetic field pulse is calculated using the result. In the second measurement sequence, a high frequency magnetic field pulse with the calculated waveform is applied together with the slice selection gradient magnetic field pulse, and a magnetic resonance signal for an image is measured.

### TECHNICAL FIELD

The present invention relates to a magnetic resonance imaging apparatus (hereinafter, referred to as an MRI apparatus) and in particular, to an MRI apparatus suitable for ultra-short echo time (UTE) imaging in which slice-selective excitation is performed using a high frequency pulse with a half waveform and the signal is measured within the UTE.

### BACKGROUND ART

In the MRI apparatus, when generating a nuclear magnetic resonance signal by exciting the nuclear spins of the object, a slice selection gradient magnetic field is applied together with a high frequency magnetic field pulse in order to selectively excite a specific region. As the high frequency magnetic field pulse, a high frequency modulated by an envelope, such as a symmetric sinc function, is usually used. The profile obtained by a Fourier transform of the high frequency magnetic field modulated by the sinc function in a frequency direction is a rectangle, and a predetermined rectangular region determined by the slice gradient magnetic field is excited.

Instead of the high frequency magnetic field pulse (this is called a full RE pulse) having the above-described symmetric function as an envelope (predetermined waveform), there is a method using a high frequency magnetic field pulse (called a half RF pulse) with a waveform of the half (partial waveform of a predetermined waveform) (PTL 1, PTL 2, and the like). The half RF pulse is a pulse using only a waveform of the first half when dividing a symmetric sinc pulse into first and second halves in a time direction with the peak as its center, for example.

In the UTE imaging proposed in PTL 1 and the like, this half RF pulse is applied to eliminate a refocusing pulse of the slice gradient magnetic field and also eliminate other elements that increase TE, that is, a dephase gradient magnetic field of a readout gradient magnetic field and a phase encoding gradient magnetic field, so that it is possible to measure a signal in a very short time from spin excitation. In this manner, since the TE can be significantly shortened in the UTE imaging, applications to imaging of the tissue with a short transverse relaxation time T2 which has been difficult to image with a conventional MRI, for example, imaging of the bone tissue are expected.

The slice refocusing pulse is applied to refocus the phase of the magnetization dispersed by the slice gradient magnetic field. In the UTE imaging, however, the slice refocusing pulse can be eliminated by applying the RF pulse including the falling time of the slice gradient magnetic field. However, at the falling time of the gradient magnetic field, the gradient magnetic field changes at a predetermined slew rate. Therefore, in order to perform excitation with the same slice thickness, it is necessary to change the high frequency magnetic field pulse according to a change in the slice gradient magnetic field. The technique of partially extending the application time while modulating a high frequency magnetic field pulse according to the change in the slice gradient magnetic field and of outputting the high frequency magnetic field pulse, which follows a frequency change caused by the slice gradient magnetic field, is known as VERSE (Variable-Rate Selective Excitation) (NPL 1 and PTL 3). This technique is also adopted in UTE imaging disclosed in PTL 1.

When calculating the high frequency magnetic field pulse that follows a spatial frequency change caused by the slice gradient magnetic field, the response (slew rate) of an ideal (for example, trapezoidal) slice gradient magnetic field pulse is generally used. However, the response of the slice gradient magnetic field that is actually applied is not necessarily an ideal slice gradient magnetic field response. In order to solve this problem, a technique has been proposed in which the hard-output gradient magnetic field response is corrected on the basis of a gradient magnetic field response measured in advance so that the gradient magnetic field is output as a more ideal response (NPL 3).

### CITATION LIST

### Patent Literature

[PTL 1] U.S. Pat. No. 5,025,216
[PTL 2] U.S. Pat. No. 5,150,053
[PTL 3] U.S. Pat. No. 4,760,336

### Non Patent Literature

[NPL 1] JMRI 25:279-289 (2007)
[NPL 2] JMR 78, 440-458 (1988)
[NPL 3] Proc. Intl. Soc. Mag. Reson. Med. 11 (2004), p628

### SUMMARY OF INVENTION

### Technical Problem

The gradient magnetic field response measured in advance is a gradient magnetic field response measured on the basis of a reference gradient magnetic field pulse and in a strict sense, is different from the gradient magnetic field response used in actual imaging. When using a half RF pulse, the high output time (vicinity of peak output) of RF pulse is a change timing of the gradient magnetic field (falling time of the gradient magnetic field). Accordingly, an estimated error of the actual gradient magnetic field response leads to a modulation error of the high frequency magnetic field pulse, causing noticeable image quality degradation. Specifically, the estimated error leads to degradation of the excitation characteristics of a slice, deviation of the slice thickness, blurring in a slice direction, and the like. In the UTE imaging, artifacts are caused from the outside of the surface.

It is an object of the present invention to prevent the degradation of the slice excitation characteristics, in particular, to improve the image quality in UTE imaging by making it possible to modulate a high frequency magnetic field pulse on the basis of a gradient magnetic field response that is actually used.

### Solution to Problem

In order to solve the above-described problems, the present invention provides a technique of measuring the slice gradient magnetic field response simply and modulating the high frequency magnetic field pulse using the actual gradient magnetic field response for each actual measurement. The MRI apparatus of the present invention calculates a slice gradient magnetic field response from a magnetic resonance signal measured by the pulse sequence using the same slice gradient magnetic field as in the imaging sequence. In the pulse sequence for calculating the slice gradient magnetic field response, the magnetic resonance signal is measured by applying the readout gradient magnetic field in the same axial direction as the slice gradient magnetic field.

Specifically, an MRI apparatus of the present invention includes: a gradient magnetic field generating unit; a signal transmission unit that generates a high frequency magnetic field pulse; a signal receiving unit that receives a magnetic resonance signal from an object; and a control unit that controls the gradient magnetic field generating unit, the signal transmission unit, and the signal receiving unit on the basis of an imaging pulse sequence. The imaging pulse sequence includes first and second measurement sequences. In the first measurement sequence, the same slice selection gradient magnetic field pulse as a slice selection gradient magnetic field pulse used in the second measurement sequence is used. The control unit includes a high frequency magnetic field pulse calculating section that calculates a waveform of the high frequency magnetic field pulse generated by the signal transmission unit using a magnetic resonance signal measured by the first measurement sequence, and controls the signal transmission unit such that the high frequency magnetic field pulse with the waveform calculated by the high frequency magnetic field pulse calculating section is applied together with the slice selection gradient magnetic field pulse in the second measurement sequence.

In addition, in the MRI apparatus of the present invention, the first measurement sequence is a sequence of collecting echo signals by applying a readout gradient magnetic field pulse to the same axis as the slice selection gradient magnetic field. The control unit calculates a phase profile of the magnetic resonance signal measured by the first measurement sequence, differentiates the phase profile in a time direction, and modulates a high frequency magnetic field pulse using the profile after the differential.

The MRI apparatus of the present invention may be applied to an MRI apparatus having an imaging pulse sequence in which a high frequency magnetic field pulse is a pulse which is asymmetric in a time axis direction, for example, a pulse generated by halving a pulse that is symmetric in the time axis direction or an imaging pulse sequence in which the intensity of a gradient magnetic field pulse changes during application of a high frequency magnetic field pulse, for example, an imaging pulse sequence in which a high frequency magnetic field pulse is also applied at the rising or falling time of the gradient magnetic field pulse.

A high frequency magnetic field pulse modulation method of the present invention is a method of modulating a high frequency magnetic field pulse for excitation of an MRI apparatus, and includes: a step of applying a first high frequency magnetic field pulse and a first slice gradient magnetic field pulse and calculating a phase profile from an echo signal generated by applying a readout gradient magnetic field at the same axis as the first slice gradient magnetic field pulse, a step of differentiating the calculated phase profile in a time axis direction, and a step of modulating a second high frequency magnetic field pulse, which is applied together with the same second slice gradient magnetic field pulse as the first slice gradient magnetic field pulse, using the profile after the differential.

Advantageous Effects of Invention

According to the MRI apparatus of the present invention, an actual gradient magnetic field response is measured immediately before imaging, and a high frequency magnetic field pulse is modulated using the measurement data. Therefore, it is possible to obtain an image without degradation of the slice excitation characteristics due to estimated error of the gradient magnetic field response. In particular, in the UTE imaging using a half RF pulse, it is possible to obtain a good image quality with no artifacts.

### BRIEF DESCRIPTION OF DRAWINGS

FIG. 1 is a view showing the outline of an entire MRI apparatus to which the present invention is applied.

FIG. 2 is a view showing the imaging procedure according to a first embodiment of the present invention.

FIG. 3 is a view showing an example of the pulse sequence that the MRI apparatus of the present invention has.

FIG. 4 is a view showing the procedure of calculating the gradient magnetic field response.

FIG. 5 is a view showing an example of a result after differentiating an echo signal measured in advance in the time direction.

FIG. 6 is a view showing the procedure of calculating the shape of a high frequency magnetic field pulse.

FIGS. 7(a) to 7(c) are views explaining the concept of rescaling in the procedure of FIG. 6.

FIG. 8(a) is a view showing the shape of a gradient magnetic field calculated from the data in pre-measurement, and FIG. 8(b) is a view showing a modulation result of the calculated high frequency magnetic field pulse.

FIG. 9 is a view showing the imaging procedure according to a second embodiment of the present invention.

### DESCRIPTION OF EMBODIMENTS

Hereinafter, embodiments of the present invention will be described.

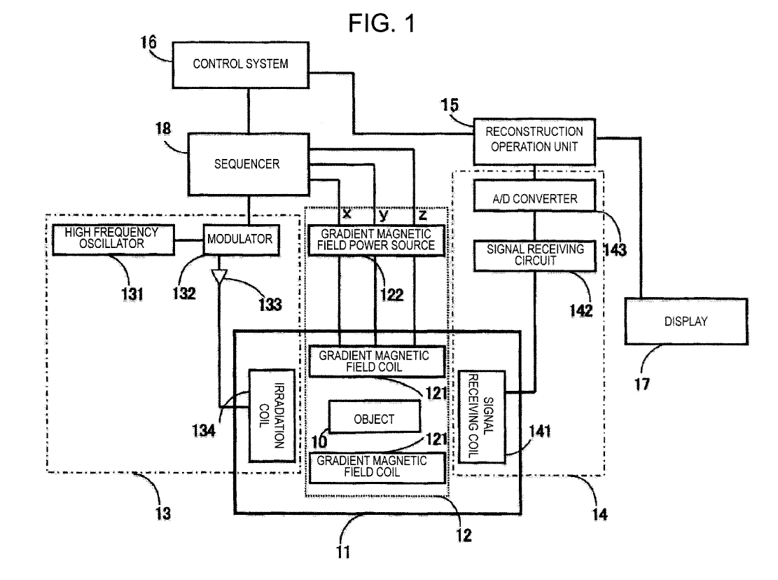

FIG. 1 shows the overall configuration of an MRI apparatus to which the present invention is applied. As shown in FIG. 1, the MRI apparatus mainly includes: a static magnetic field generating system 11 which generates a uniform static magnetic field around an object 10; a gradient magnetic field generating system 12 which gives a magnetic gradient in three axial directions (x, y, and z) perpendicular to the static magnetic field; a high frequency magnetic field generating system 13 which applies an RF pulse to the object 10; a signal receiving system 14 which detects a magnetic resonance signal (MR signal) generated from the object 10; a reconstruction operation unit 15 which reconstructs a tomographic image, a spectrum, or the like of the object using the MR signal received by the signal receiving system 14; and a control system 16 which controls operations of the gradient magnetic field generating system 12, the high frequency magnetic field generating system 13, and the signal receiving system 14.

Although not shown, a magnet, such as a permanent magnet or a superconducting magnet, is disposed in the static magnetic field generating system 11, and the object is placed in the bore of the magnet. The gradient magnetic field generating system 12 includes gradient magnetic field coils 121 in the three axial directions and a gradient magnetic field power source 122 which drives the gradient magnetic field coils 121. The high frequency magnetic field generating system 13 includes: a high frequency oscillator 131; a modulator 132 which modulates a high frequency signal generated by the high frequency oscillator 131; a high frequency amplifier 133 which amplifies a modulated high frequency signal; and an irradiation coil 134 which receives a high frequency signal from the high frequency amplifier 133 and irradiates the object 10 with the high frequency magnetic field pulse.

Frequency and waveform (envelope) of the RF pulse are determined by the frequency of the high frequency oscillator 131 and the modulated signal from the modulator 132, respectively, and an RF pulse with a desired waveform can be output by changing the modulated signal from the modulator 132 by control of the control system 16.

The signal receiving system 14 includes: a signal receiving coil 141 which detects an MR signal from the object 10; a signal receiving circuit 142 which receives the signal detected by the signal receiving coil 141, and an A/D converter 143 which converts an analog signal received by the signal receiving circuit 142 into a digital signal at a predetermined sampling frequency. The reconstruction operation unit 15 performs operations, such as correction calculation and a Fourier transform, on the digital signal output from the A/D converter 143 in order to reconstruct an image. The processing result in the reconstruction operation unit 15 is displayed on a display 17.

The control system 16 controls the operation of the entire apparatus described above and in particular, includes a sequencer 18 for controlling the operations of the gradient magnetic field generating system 12, the high frequency magnetic field generating system 13, and the signal receiving system 14 at the predetermined timing determined by an imaging method and a storage unit (not shown) which stores a parameter and the like required for control. In addition, the control system 16 performs an operation for determining the waveform of an RF pulse or creates a pulse sequence, which will be described later, and transmits the result to the gradient magnetic field generating system 12 and the signal transmission system 13, such as the modulator 132, through the sequencer 18. The timing of each magnetic field pulse generation controlled by the sequencer 18 is called a pulse sequence, and various kinds of pulse sequences are stored in the storage unit in advance. By reading and executing a desired pulse sequence, imaging is performed. The MRI apparatus of the present invention has a pulse sequence of UTE imaging, which will be described later, as the pulse sequence.

The control system 16 and the reconstruction operation unit 15 include user interfaces allowing the user to set the conditions or the like required for their processing. Through these user interfaces, selection of an imaging method or setting of a parameter required for execution of the pulse sequence is performed.

The MRI apparatus of the present invention is characterized in that, in the above-described configuration, an RF pulse applied while a slice gradient magnetic field pulse for UTE imaging or the like is changing is controlled corresponding to the slice gradient magnetic field pulse. Hereinafter, embodiments of the operation of the MRI apparatus of the present invention will be described focusing on the RF pulse control method.

### First Embodiment

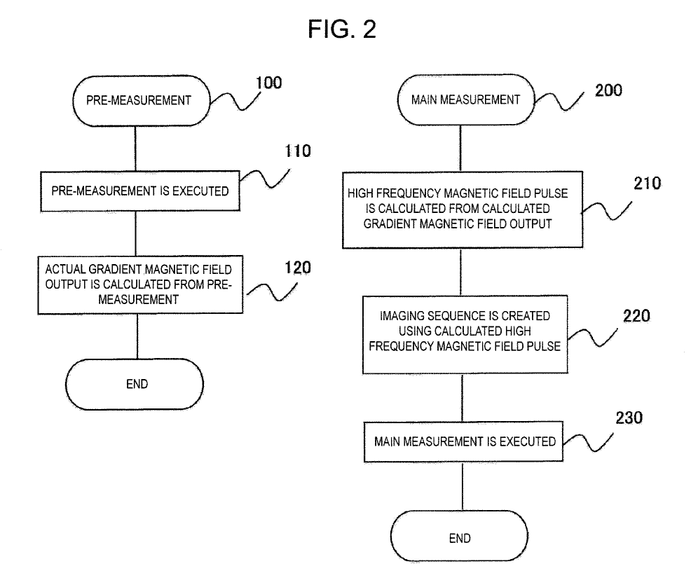

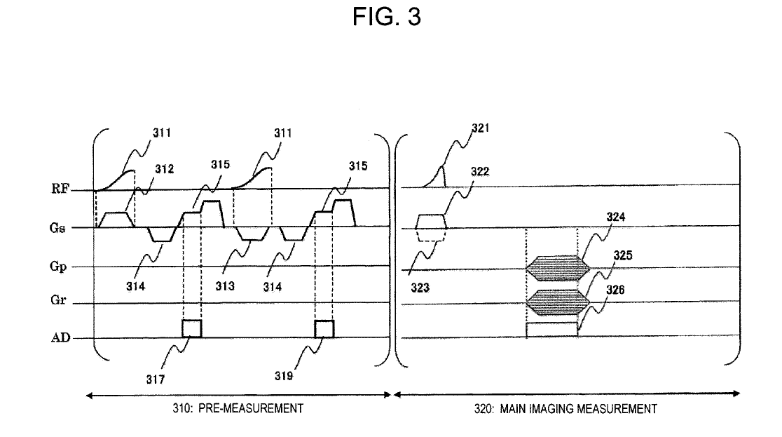

FIG. 2 shows an operation procedure of the present embodiment, and FIG. 3 shows a pulse sequence according to the present embodiment.

As shown in FIG. 2, imaging of the present embodiment includes pre-measurement 100 for measuring a gradient magnetic field pulse and main measurement 200 using the RE pulse shape determined from the result of the pre-measurement.

The pre-measurement 100 is measurement for calculating the output of the slice gradient magnetic field applied in the same conditions as the slice gradient magnetic field used in the main measurement 200, and includes a step 110 of executing a pre-measurement pulse sequence 310 and a subsequent step 120 of calculating the gradient magnetic field output (response of the actual gradient magnetic field) that are shown in FIG. 3. In the present embodiment, the main measurement 200 is measurement based on the UTE imaging sequence, and includes a step 210 of calculating the RF pulse using the gradient magnetic field response calculated in the pre-measurement 100, a step 220 of creating an imaging pulse sequence 320 using the RF pulse calculated in the calculation step 210, and a step 230 of executing the created imaging sequence 320.

The imaging pulse sequence 320 is a known UTE imaging sequence. Briefly speaking, as shown on the right side of FIG. 3, a half RF pulse 321 is applied together with a slice gradient magnetic field pulse 322, and signal measurement 326 is performed while applying readout gradient magnetic fields 324 and 325 in two axial directions. In the UTE imaging, a half RF pulse is used, and the signal measurement 326 is started from the rise time of the readout gradient magnetic fields 324 and 325. Accordingly, since no gradient magnetic field for dephase is required, signal measurement of the very short TE is possible.

The above-described measurement 326 is repeated by changing the polarity of a slice gradient magnetic field pulse 323 applied simultaneously with the half RF pulse 321, thereby acquiring a pair of signals. When the slice axis of k space is considered, the echo obtained by excitation by the half RF pulse is measurement data on one side from the origin. However, by performing complex addition of signals acquired by two measurements in which the polarity of the slice gradient magnetic field is changed, it is possible to acquire a signal equivalent to that when a full RF pulse is used.

By repeating the pair of measurements while changing the intensity of the readout gradient magnetic field, data required for two-dimensional image reconstruction can be acquired.

Hereinafter, based on such a main imaging pulse sequence, details of each step shown in FIG. 2 will be described.

### <<Step 110>>

The pre-measurement pulse sequence 310 is executed. In the pre-measurement pulse sequence 310, as shown on the left side of FIG. 3, a half RF pulse 311 is applied while applying the same slice gradient magnetic field 312 as the slice gradient magnetic field 322 in the main imaging pulse sequence 320 and then readout gradient magnetic fields 314 and 315 are applied to the same axis as the slice gradient magnetic field to measure 317 an echo signal. Then, the same measurement 319 is performed while applying the same slice gradient magnetic field 313 as the slice gradient magnetic field 323 in the main imaging pulse sequence 320, thereby acquiring an echo signal.

This pre-measurement pulse sequence 310 is characterized in that the readout gradient magnetic fields 314 and 315 are applied in the same axis direction as the slice gradient magnetic fields 312 and 313, and accordingly the information of the slice gradient magnetic field response can be calculated from the echo signal. In addition, in the pre-measurement shown in FIG. 3, two measurements in which the polarities of the slice gradient magnetic fields 312 and 313 are changed are performed corresponding to a pair of (positive and negative) slice gradient magnetic fields used in the main measurement 320. However, it is also possible to perform measurement using a gradient magnetic field pulse with one polarity and to estimate a gradient magnetic field pulse response with another polarity from the result (to invert the sign).

### <<Step 120>>

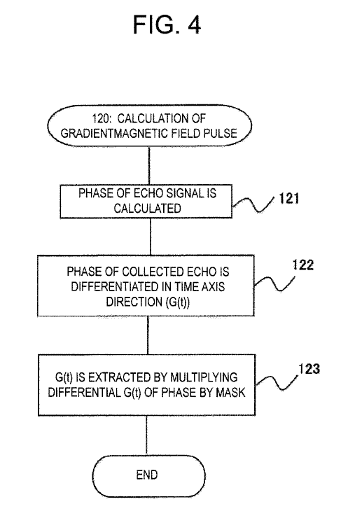

The gradient magnetic field pulses 312 and 313 are calculated using a pair of echo signals obtained in step 110. FIG. 4 shows details of this step 120.

First, for each of the signals (complex signal) acquired by two measurements, the phase profile of the signal is calculated (step 121). The phase can be calculated by calculating the arc tangent of real and imaginary parts of the complex signal. As will be described below, the phase is proportional to the integral value of the slice gradient magnetic field that is actually applied. In addition, all phases calculated for all sampling points are called the phase profile.

Transverse magnetization of a signal measured by applying the readout gradient magnetic field to the axis of the slice gradient magnetic field can be expressed by the following Expression (1).

[Expression 1]

M_{xy}(x)=i·γ·M₀∫₀^{T}rf(t)·e^{-iγx∫G(s)ds}dt (1)

Here, χ is a position in the slice direction, M₀ is initial magnetization, rf(t) is a high frequency magnetic field pulse, and G(s) is a gradient magnetic field pulse in the slice direction. This expresses the gradient magnetic field intensity in a direction of the time axis s.

As shown in Expression (2), an echo signal m(t) calculated by pre-measurement is expressed by Expression in the integral sign of Expression (1).

[Expression 2]

m(t)=rf(t)·e^{-iγx∫G(s)ds}dt (2)

In addition, the phase φ(t) of the acquired echo signal is expressed by Expression (3).

[Expression 3]

φ(t)=−i·γ·x∫G(s)ds (3)

That is, in step 121, the left side of Expression (3) is calculated, and this is proportional to the integral result of G(s).

Then, the phase profile of the measurement signal calculated in step 121 is differentiated in a direction of the time axis (t) (step 122). The differential result of the phase profile is proportional to a gradient magnetic field pulse, as shown in Expression (4). In addition, in Expression (4), G(s) is denoted as G(t) according to the time axis t of the phase.

$$\begin{matrix}[ Expression 4 ] & \\ \frac{d φ ( t )}{d t} = - i \cdot γ \cdot x \cdot G ( t ) & ( 4 )\end{matrix}$$

By multiplying the differentiation result of the phase by the following mask mask(t), G(t) is extracted from Expression (5) (step 123).

$$\begin{matrix}[ Expression 5 ] & \\ mask ( t ) = 1 ( rf ( t ) \neq 0 ) , 0 ( rf ( t ) = 0 ) \\ G ( t ) = abs ( mask ( t ) \times \frac{d φ}{d t} ) & ( 5 )\end{matrix}$$

In this manner, it is possible to calculate the output G(t) of the gradient magnetic field pulse.

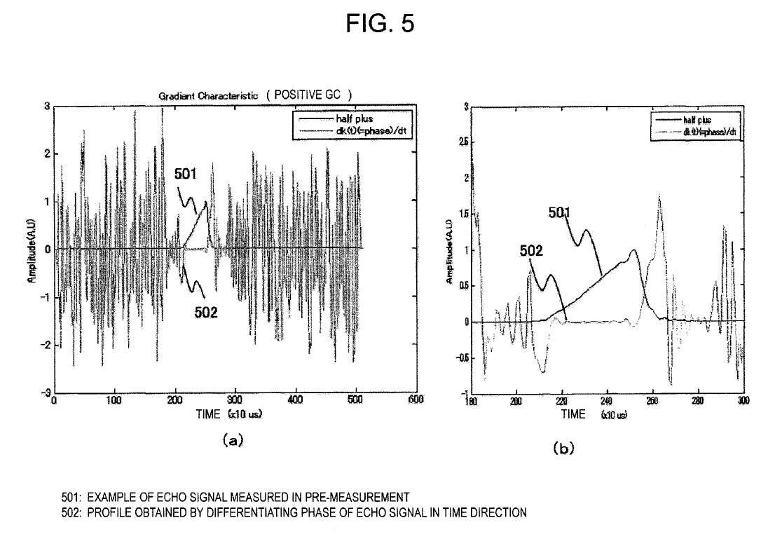

FIG. 5 shows an echo signal 501 obtained by pre-measurement and a profile 502 (result obtained by the above Expression (4)) obtained by differentiating the phase in the time direction. FIG. 5(b) is an enlarged view of a main portion of FIG. 5(a).

### <<Step 210>>

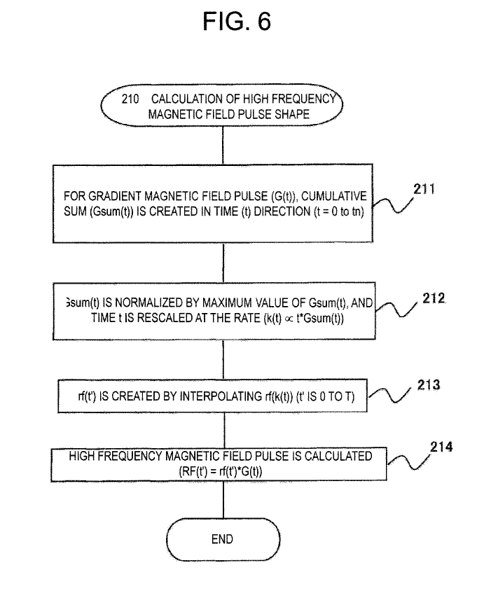

The shape of the half RF pulse used in the main imaging is calculated on the basis of the gradient magnetic field pulse output G(t) obtained in step 120. That is, the half RE pulse designed as the main imaging pulse sequence is modulated by the gradient magnetic field output G(t) obtained in step 120. FIG. 6 shows details of this step 210.

First, rescaling of the sampling time of a half RF pulse (hereinafter, referred to as an original RF pulse) rf designed as a high frequency magnetic field pulse of the main measurement pulse sequence is performed (steps 211 and 212). When a gradient magnetic field changes during the application of the excitation by the RE pulse, the sampling interval k(t) in the slice direction (kz direction) of k space also changes and is no longer equidistant. On the other hand, in the case of hard control of the RE pulse, control is made at equal sampling intervals. Processing of changing the time interval of RF pulses corresponding to the changing sampling interval in the kz direction is the rescaling.

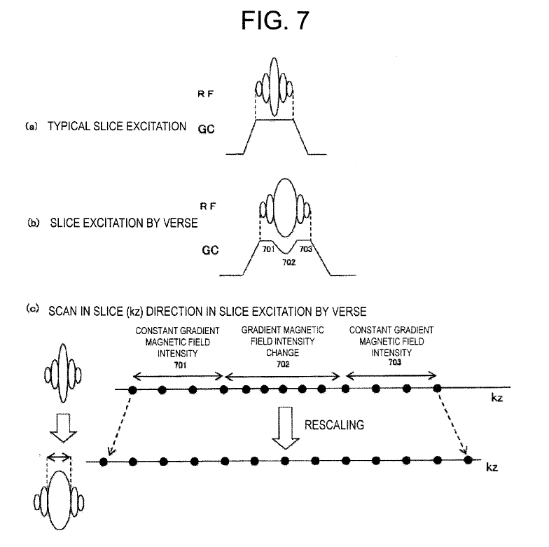

The concept of rescaling will be described with reference to FIG. 7 with the excitation when a full RF pulse is used as an example. In the drawing, (a) shows a typical slice excitation in which the RF pulse is applied when the intensity of the gradient magnetic field pulse is constant, (b) shows a slice excitation in which the gradient magnetic field pulse changes during the application of the RF pulse, and the horizontal axis is a time axis. In (b), the intensity of the gradient magnetic field pulse during the application of the RF pulse is constant in regions 701 and 703 at both ends and is decreased in a central region 702. In this case, in a k space scan (kz scan) in the slice direction, the sampling interval in the kz direction in the central region 702 is shorter than that in the regions 701 and 703, as shown on the kz axis on the upper side of (c). Processing of changing this to the equal interval as shown on the kz axis on the lower side of (c) is the rescaling, and this means extending the RF pulse shape shown in (a) in the time axis direction according to a change in the gradient magnetic field intensity, that is, the sampling interval in kz space.

Specifically, as shown in Expression (6), the cumulative sum Gsum(t) of the gradient magnetic field pulse G(s) obtained in step 120 is generated (step 211), the cumulative sum Gsum(t) is normalized by the maximum value Max(Gsum(t)), and rescaling of the sampling interval t in the time direction is performed at the rate (step 212).

[Expression 6]

k(t)=t*Gsum(t)/Max(Gsum(t)) (6)

Here, k(t) is equivalent to the sampling point in the slice direction of k space.

The waveform of the RF pulse obtained by rescaling the original RE pulse rf(k(t)) extends in the time axis direction. Accordingly, rf(t′) is created by interpolating the values of sampling points arrayed at equal distances in the time direction (t is sampling points arrayed at equal distances in a range of 0 to T) (step 213).

Finally, using rf(t′) after rescaling and the gradient magnetic field output G(t) obtained in step 120, an RF pulse 311 (RF(t′)) in the main imaging is calculated by Expression (7) (step 214).

[Expression 7]

RF(t′)=rf(t′)×(G(t)/G(t)_max) (7)

In Expression (7), G(t)_max is a maximum value of G(t). That is, RF(t′) is calculated by multiplying rf(t′) by the result obtained by normalizing G(t) with the maximum value.

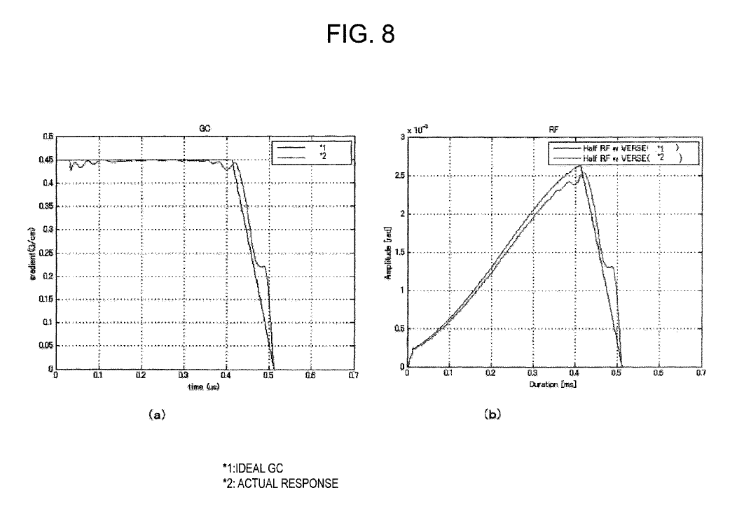

FIG. 8(a) shows a response (result of Expression (5)) of the gradient magnetic field pulse measured in the present embodiment with respect to an ideal gradient magnetic field pulse, and FIG. 8(b) shows a result (result of Expression (7)) after modulating a high frequency magnetic field pulse using the response of the gradient magnetic field pulse measured in the present embodiment.

### <<Step 220>>

The imaging pulse sequence of the main measurement is created using the RE pulse RF(t′) calculated in step 210.

### <<Step 230>>

The imaging pulse sequence created in step 210 is executed. This pulse sequence is obtained by modulating the half RF pulse shape on the basis of the pulse sequence 320 shown in FIG. 3, and other pulses are the same as described above. Measurement is repeatedly performed while changing the readout gradient magnetic field, and the acquired MR signal (2D data) is transmitted to the reconstruction operation unit 15. The reconstruction operation unit 15 reconstructs an image using the MR signal and displays the image on the display 17 and also stores the image on a storage medium (not shown) or transmits it to other modalities as necessary.

According to the present embodiment, since means configured to measure an actual gradient magnetic field response immediately before imaging and means configured to modulate a high frequency magnetic field pulse using the measurement data are provided, it is possible to obtain a good image quality with no artifacts in the UTE imaging using a half RE pulse.

### Second Embodiment

Next, an embodiment in which the present invention is applied to an MRI apparatus that performs imaging continuously while changing the conditions of slice selection will be described. Examples of continuous imaging, which is an object of the present invention, include dynamic imaging in which imaging is performed while changing the slice section or the imaging conditions interactively according to the behavior of the object, such as bending motion of the joint, imaging of switching from 3D imaging to 2D imaging, or the like.

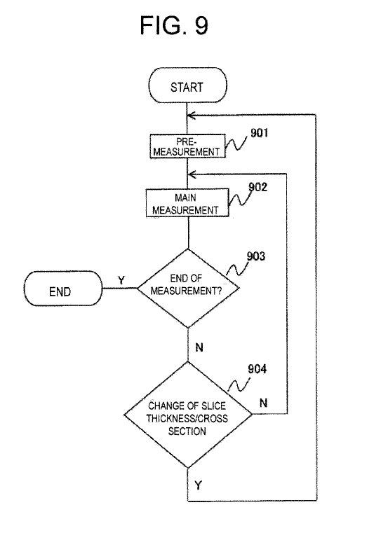

FIG. 9 shows an imaging procedure of the present embodiment. Also in the present embodiment, in order that the shape of the RF pulse used in main measurement is determined in advance of the main measurement, performing the pre-measurement of the response of the gradient magnetic field pulse is the same as in the first embodiment. That is, also in the present embodiment, the pulse sequence 310 in the pre-measurement shown in FIG. 3 is executed using the same slice gradient magnetic field as the slice gradient magnetic field used in the imaging pulse sequence of the main measurement, thereby acquiring an echo signal (step 901). The response of the slice gradient magnetic field is calculated by calculating the phase of the acquired echo signal and differentiating it.

Then, the waveform of the RF pulse used in the main measurement is calculated using the calculated response of the slice gradient magnetic field, and the imaging pulse sequence is executed using the calculated RF pulse in the subsequent main imaging (step 902). Calculating the waveform of the RE pulse is performed according to the procedure shown in FIGS. 4 and 6, as in the first embodiment.

When there is a change in the slice thickness and/or the slice section after the main measurement (step 904), the process returns to pre-measurement step 901 to measure the slice gradient magnetic field response and calculate the RF pulse shape, and the main measurement is performed under the changed slice conditions. When there is no change in the slice conditions, the main measurement is repeated until the imaging ends (step 903).

According to the present embodiment, the RF pulse can be changed in real time in conjunction with a change in the slice conditions. Therefore, also in imaging during which the response of the slice gradient magnetic field changes, it is possible to acquire a good image.

Until now, as embodiments of the present invention, each embodiment in which the present invention is applied to UTE imaging has been described. However, the present invention is not limited to the UTE imaging, and may be applied to any pulse sequence as long as it is a pulse sequence in which the slice gradient magnetic field intensity changes during excitation by the RF pulse. As examples of such imaging, two-dimensional cylindrical excitation (Magn. Reson. Med., 17(2):390-401, 1991, J. Magn. Reson., 87:639-645, 1990) and the like may be mentioned. In any case, in pre-measurement, a signal is measured with the readout gradient magnetic field as a slice axis using the main measurement and the slice gradient magnetic field pulse, and the slice gradient magnetic field response can be acquired from the measured signal by calculation.

### REFERENCE SIGNS LIST

11: static magnetic field generating system
12: gradient magnetic field generating system
13: high frequency magnetic field generating system
14: signal receiving system
15: reconstruction operation unit
16: control system
17: display
18: sequencer

1. A magnetic resonance imaging apparatus comprising:
a gradient magnetic field generating unit;
a signal transmission unit that generates a high frequency magnetic field pulse;
a signal receiving unit that receives a magnetic resonance signal from an object; and
a control unit that controls the gradient magnetic field generating unit, the signal transmission unit, and the signal receiving unit on the basis of an imaging pulse sequence,
wherein the imaging pulse sequence includes first and second measurement sequences, and in the first measurement sequence, the same slice selection gradient magnetic field pulse as a slice selection gradient magnetic field pulse used in the second measurement sequence is used, and
the control unit includes a high frequency magnetic field pulse calculating section that calculates a waveform of the high frequency magnetic field pulse generated by the signal transmission unit using a magnetic resonance signal measured by the first measurement sequence, and controls the signal transmission unit such that the high frequency magnetic field pulse with the waveform calculated by the high frequency magnetic field pulse calculating section is applied together with the slice selection gradient magnetic field pulse in the second measurement sequence.

2. The magnetic resonance imaging apparatus according to claim 1,
wherein the first measurement sequence is a sequence of collecting echo signals by applying a readout gradient magnetic field pulse to the same axis as the slice selection gradient magnetic field.

3. The magnetic resonance imaging apparatus according to claim 2,
wherein the control unit calculates a phase profile of the magnetic resonance signal measured by the first measurement sequence, differentiates the phase profile in a time direction, and modulates the high frequency magnetic field pulse using the profile after the differential.

4. The magnetic resonance imaging apparatus according to claim 1,
wherein the slice selection gradient magnetic field used in the first and second measurement sequences is a slice selection gradient magnetic field whose intensity changes during application of the high frequency magnetic field pulse.

5. The magnetic resonance imaging apparatus according to claim 4,
wherein the slice selection gradient magnetic field used in the first and second measurement sequences has an approximately trapezoidal profile having a rising time and a falling time, and
the control unit applies the high frequency magnetic field pulse during slice selection gradient magnetic field application including the rising time and/or the falling time of the slice selection gradient magnetic field.

6. The magnetic resonance imaging apparatus according to claim 1,
wherein the high frequency magnetic field pulse in the first and second measurement sequences is a high frequency magnetic field pulse with an asymmetric shape in a time axis direction.

7. The magnetic resonance imaging apparatus according to claim 6,
wherein the high frequency magnetic field pulse in the first and second measurement sequences is an asymmetric high frequency magnetic field pulse generated by halving a high frequency magnetic field pulse which is symmetric with respect to one point in the time axis direction.

8. The magnetic resonance imaging apparatus according to claim 1, wherein:
the imaging pulse sequence includes a plurality of second measurement sequences with different slice selection gradient magnetic field application conditions, and
the control unit, each time that slice selection gradient magnetic field application conditions of the second measurement sequence are changed, executes the first measurement sequence and calculates a waveform of a high frequency magnetic field pulse in advance of the change.

9. The magnetic resonance imaging apparatus according to claim 3,
wherein the control unit rescales a basic high frequency magnetic field pulse according to a time axis of the phase profile.

10. A method of modulating a high frequency magnetic field pulse for excitation of a magnetic resonance imaging apparatus, the high frequency magnetic field pulse modulation method comprising:
a step of applying a first high frequency magnetic field pulse and a first slice gradient magnetic field pulse and calculating a phase profile from an echo signal generated by applying a readout gradient magnetic field at the same axis as the first slice gradient magnetic field pulse,
a step of differentiating the calculated phase profile in a time axis direction, and
a step of modulating a second high frequency magnetic field pulse, which is applied together with the same second slice gradient magnetic field pulse as the first slice gradient magnetic field pulse, using the profile after the differential.

11. The high frequency magnetic field pulse modulation method according to claim 10,
wherein the modulation step is a step of rescaling a basic high frequency magnetic field pulse according to a time axis of the phase profile.

12. The high frequency magnetic field pulse modulation method according to claim 10,
wherein the first and second slice gradient magnetic field pulses are pulses whose intensity changes during high frequency magnetic field pulse application.

13. The high frequency magnetic field pulse modulation method according to claim 10,
wherein the first and second high frequency magnetic field pulses are asymmetric high frequency magnetic field pulses generated by halving a high frequency magnetic field pulse which is symmetric with respect to one point in the time axis direction.
